(19) United States
(12) Patent Application Publication
(10) Pub. No.: US 2022/0328094 A1
(43) Pub. Date: Oct. 13, 2022

(54) SEMICONDUCTIVE MEMORY DEVICE

(71) Applicants: Nezam Rohbani, Lavasan (IR); Sina Darabi-Moghaddam, Tehran (IR); Hamid Sarbazi-Azad, Tehran (IR)

(72) Inventors: Nezam Rohbani, Lavasan (IR); Sina Darabi-Moghaddam, Tehran (IR); Hamid Sarbazi-Azad, Tehran (IR)

(73) Assignees: Nezam Rohbani, Lavasan (IR); Sina Darabi-Moghaddam, Tehran (IR); Hamid Sarbazi-Azad, Tehran (IR)

(21) Appl. No.: 17/846,102

(22) Filed: Jun. 22, 2022

Related U.S. Application Data
(63) Continuation-in-part of application No. PCT/IB2022/052021, filed on Mar. 8, 2022.
(60) Provisional application No. 63/159,576, filed on Mar. 11, 2021.

(51) Int. Cl. G11C 11/4091; G11C 11/4094; G11C 11/408

(52) U.S. Cl. CPC G11C 11/4091; G11C 11/4094; G11C 11/4085

(57) ABSTRACT

A semiconductive memory device. The semiconductive memory device includes a sense amplifier. The sense amplifier is configured to drive one of a left node and a right node of the sense amplifier to a data voltage level associated with stored data in a memory cell of the semiconductive memory device. The sense amplifier is configured to drive the one of the left node and the right node responsive to a voltage level of each of the left node and the right node being equal to a primary voltage level.

### CROSS-REFERENCE TO RELATED APPLICATION

This application is a continuation-in-part of International Patent Application PCT/IB2022/052021, filed on Mar. 8, 2022, and entitled “SEMICONDUCTIVE MEMORY DEVICE,” which takes priority from U.S. Provisional Patent Application Ser. No. 63/159,576 filed on Mar. 11, 2021, and entitled “PRECHARGE-FREE DRAM”, which are all incorporated herein by reference in their entirety.

### TECHNICAL FIELD

The present disclosure generally relates to computer systems, and particularly, to dynamic random-access memories.

### BACKGROUND

Due to an increase in memory size of computer systems, from high-performance computers to low-power embedded devices, memory subsystem contributes to a large amount of power/energy consumption in computer systems. Recent evaluations reveal that memory subsystems account for 25%-57% of system power consumption.

Among different units of a memory subsystem, dynamic random-access memory (DRAM) chips consume a major portion of power/energy. A DRAM memory chip may be composed of three main components: 1-memory cell array that stores data in a matrix of memory cells, 2-peripherals that allow access memory cells, and 3-input/output (I/O) interface that translate external signals for activating peripheral circuits.

Three main operations that manipulate memory cell arrays may include: read, write, and refresh. Each of read, write, and refresh operations may be initiated by activating a row of cells. To maximize a ratio of memory cell arrays area to peripherals area and I/O interface area, and to boost performance of DRAM, commands may be issued to a bunch of DRAM memory chips for parallel read/write/refresh operations. Thus, a large number of cells, for example 64 K cells in DDR4, may be activated simultaneously, while many of activated cells may not be read or written during an access operation, resulting in excessive power dissipation.

In conventional DRAMs, any activation requires precharing corresponding bitlines. Precharge phase may be mandatory to set a starting point for sense amplifiers (SAs). Two bitlines may be paired and connected to an SA that determines stored value of a connected cell to one of two bitlines by detecting a tiny voltage perturbation on one bitline compared to another as a reference voltage. After sensing phase, one of bitlines may be discharged to 0 while another may be charged to a drain voltage (VDD).

DRAMs may generally precharge bitlines to VDD/2. Charging a large number of bitline pairs to VDD/2, and then charging one bitline in each pair to VDD and discharging another to 0 in activation phase, dissipate considerable amount of energy. Precharge phase may also contribute to a latency of DRAMs because bitlines may need some time to be sufficiently charged or discharged to VDD/2.

There is, therefore, a need for a DRAM that mitigates power dissipation and time consumption of precharge phase. There is also a need for a method for accessing a memory cell in a DRAM that may not require a precharge phase.

### SUMMARY

This summary is intended to provide an overview of the subject matter of this patent, and is not intended to identify essential elements or key elements of the subject matter, nor is it intended to be used to determine the scope of the claimed implementations. The proper scope of this patent may be ascertained from the claims set forth below in view of the detailed description below and the drawings.

In one general aspect, the present disclosure describes an exemplary method for accessing a memory cell in a semiconductive memory device. An exemplary method may include driving one of a left node and a right node of a sense amplifier to a data voltage level. An exemplary data voltage level may be associated with stored data in the memory cell. In an exemplary embodiment, one of the left node and the right node may be driven to the data voltage level responsive to a voltage level of each of the left node and the right node being equal to a primary voltage level. An exemplary primary voltage level may be equal to one of a logic high voltage or a logic low voltage.

An exemplary method may further include equalizing a bitline left and a bitline right of the semiconductive memory device and charge sharing between the memory cell and one of the bitline left and the bitline right. In an exemplary embodiment, the bitline left and the bitline right may be equalized prior to driving the one of the left node and the right node. In an exemplary embodiment, the bitline left and the bitline right may be equalized utilizing a charge sharing circuit. Exemplary charges of the memory cell and the one of the bitline left and the bitline right may be shared utilizing the charge sharing circuit.

In an exemplary embodiment, driving the one of the left node and the right node may include decoupling the bitline left from the left node, decoupling the bitline right from the right node, activating a pair of cross-coupled inverters of the sense amplifier, and activating one of a left inverter and a right inverter of the sense amplifier. An exemplary bitline left may be decoupled from the left node responsive to a first coupling transistor of the charge sharing circuit being deactivated. An exemplary bitline right may be decoupled from the right node responsive to a second coupling transistor of the charge sharing circuit being deactivated. An exemplary pair of cross-coupled inverters may be activated responsive to an enabling signal being driven to a first voltage level. In an exemplary embodiment, the one of the left inverter and the right inverter may be activated responsive to a respective boost signal being driven to a second voltage level. An exemplary input of the left inverter may be coupled to the left node. An exemplary output of the left inverter may be coupled to the right node. An exemplary input of the right inverter may be coupled to the right node. An exemplary output of the right inverter may be coupled to the left node.

In an exemplary embodiment, equalizing the bitline left and the bitline right may include coupling the bitline left to the bitline right, coupling the bitline left to the left node, and coupling the bitline right to the right node. An exemplary bitline left may be coupled to the bitline right responsive to an equalizing transistor of the charge sharing circuit being activated. An exemplary bitline left may be coupled to the left node responsive to the first coupling transistor being activated. An exemplary bitline right may be coupled to the right node responsive to the second coupling transistor being activated.

In an exemplary embodiment, charge sharing between the memory cell and the one of the bitline left and the bitline right may include decoupling the bitline left from the bitline right and coupling the memory cell to the one of the bitline right and the bitline left. An exemplary bitline left may be decoupled from the bitline right responsive to the equalizing transistor being deactivated. An exemplary memory cell may be coupled to the one of the bitline right and the bitline left responsive to a wordline of the semiconductive memory device being driven to a third voltage level.

An exemplary method may further include driving each of the bitline left and the bitline right to the data voltage level. In an exemplary embodiment, each of the bitline left and the bitline right may be driven to the data voltage level utilizing the charge sharing circuit.

In an exemplary embodiment, driving each of the bitline left and the bitline right may include coupling the bitline left to the bitline right, coupling the bitline left to the one of the left node and the right node, and coupling the bitline right to the one of the left node and the right node. An exemplary bitline left may be coupled to the bitline right responsive to the equalizing transistor being activated. An exemplary bitline left may be coupled to the one of the left node and the right node responsive to a respective coupling transistor of the first coupling transistor and a third coupling transistor of the charge sharing circuit being activated. An exemplary bitline right may be coupled to the one of the left node and the right node responsive to a respective coupling transistor of the second coupling transistor and a fourth coupling transistor of the charge sharing circuit being activated.

Other exemplary systems, methods, features and advantages of the implementations will be, or will become, apparent to one of ordinary skill in the art upon examination of the following figures and detailed description. It is intended that all such additional systems, methods, features and advantages be included within this description and this summary, be within the scope of the implementations, and be protected by the claims herein.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1A shows a flowchart of a method for accessing a memory cell in a semiconductive memory device, consistent with one or more exemplary embodiments of the present disclosure.

FIG. 1B shows a flowchart of a method for equalizing a bitline left and a bitline right of a semiconductive memory device, consistent with one or more exemplary embodiments of the present disclosure.

FIG. 1C shows a flowchart of a method for charge sharing between a memory cell and one of a bitline left and a bitline right, consistent with one or more exemplary embodiments of the present disclosure.

FIG. 1D shows a flowchart of a method for driving one of a left node and a right node of a sense amplifier to a data voltage level, consistent with one or more exemplary embodiments of the present disclosure.

FIG. 1E shows a flowchart of a method for driving each of a bitline left and a bitline right to a data voltage level, consistent with one or more exemplary embodiments of the present disclosure.

FIG. 2 shows a schematic of a semiconductive memory device, consistent with one or more exemplary embodiments of the present disclosure.

FIG. 3 shows voltage levels of a bitline left, a bitline right, and control signals in different time periods for accessing a bitline left, consistent with one or more exemplary embodiments of the present disclosure.

FIG. 4 shows a high-level functional block diagram of a computer system, consistent with one or more exemplary embodiments of the present disclosure.

FIG. 5 shows voltage levels of a memory cell, bitlines, and nodes of a sense amplifier, consistent with one or more exemplary embodiments of the present disclosure.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well known methods, procedures, components, and/or circuitry have been described at a relatively high-level, without detail, in order to avoid unnecessarily obscuring aspects of the present teachings.

The following detailed description is presented to enable a person skilled in the art to make and use the methods and devices disclosed in exemplary embodiments of the present disclosure. For purposes of explanation, specific nomenclature is set forth to provide a thorough understanding of the present disclosure. However, it will be apparent to one skilled in the art that these specific details are not required to practice the disclosed exemplary embodiments. Descriptions of specific exemplary embodiments are provided only as representative examples. Various modifications to the exemplary implementations will be readily apparent to one skilled in the art, and the general principles defined herein may be applied to other implementations and applications without departing from the scope of the present disclosure. The present disclosure is not intended to be limited to the implementations shown, but is to be accorded the widest possible scope consistent with the principles and features disclosed herein.

Herein is disclosed an exemplary semiconductive memory device and an exemplary method for accessing a memory cell in the semiconductive memory device. An exemplary semiconductive memory device may utilize a voltage, that is, 0 or a drain voltage (VDD) on a bitline pair to determine a stored value in a corresponding cell connected to each bitline. When a voltage on a cell is equal to a voltage of a connected bitline (that is, both are 0 or VDD), no voltage change may occur on bitlines and almost no power may be dissipated. A flip on voltage values of bitlines may occur only when a voltage of a cell differs from a voltage of bitlines. An exemplary semiconductive memory device may include a sense amplifier (SA). An exemplary sense amplifier may sense low power signals from a bitline that represents a data bit stored in a memory cell, and amplify a small voltage swing to recognizable logic levels so the data bit can be interpreted properly by a logic circuit outside an exemplary memory. A pair of input/output nodes of an exemplary SA may be connected to a pair of bitlines. An exemplary sense amplifier may drive a voltage of one of input/output nodes to a voltage of a memory cell connected to one of bitlines. An exemplary sense amplifier may further include cross-coupled inverters and a pair of inverters that are accordingly activated/deactivated. Specifically, an exemplary left inverter may be activated when a memory cell is connected to a left bitline. As a result, an exemplary left inverter and cross-coupled inverters may drive a left node of an SA to a voltage of a memory cell connected to a left bitline. Conversely, an exemplary right inverter may be activated when a memory cell is connected to a right bitline. As a result, an exemplary right inverter and cross-coupled inverters may drive a right node of an SA to a voltage of a memory cell connected to a right bitline. In other words, the left node may be activated when the left bitline is connected to the memory cell, and the right node may be activated when the right bitline is connected to the memory cell.

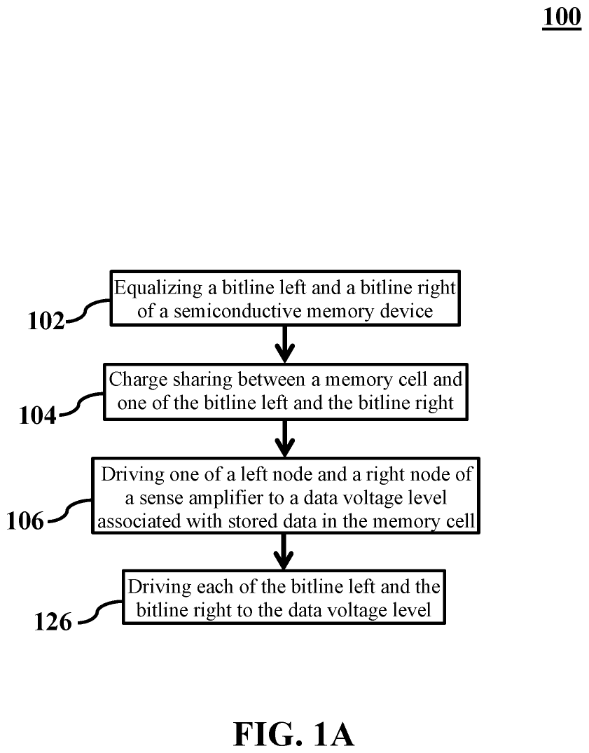

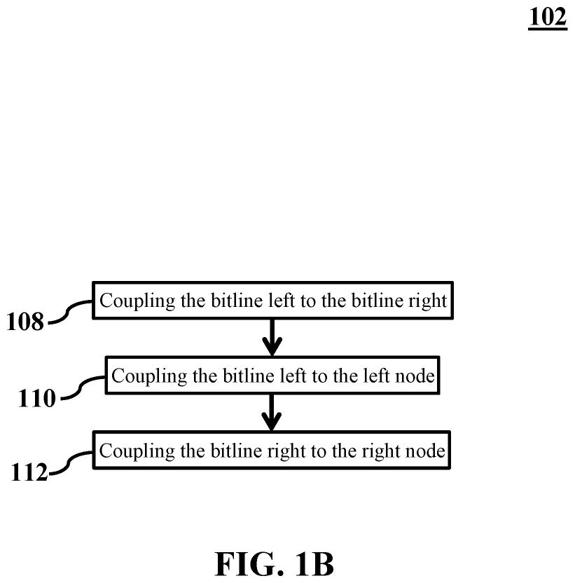

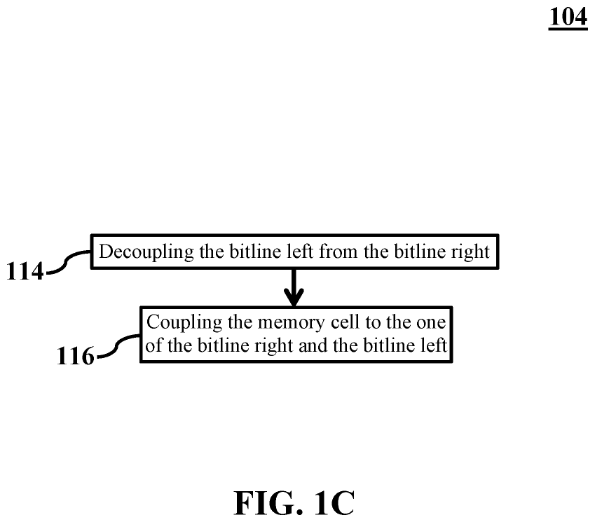

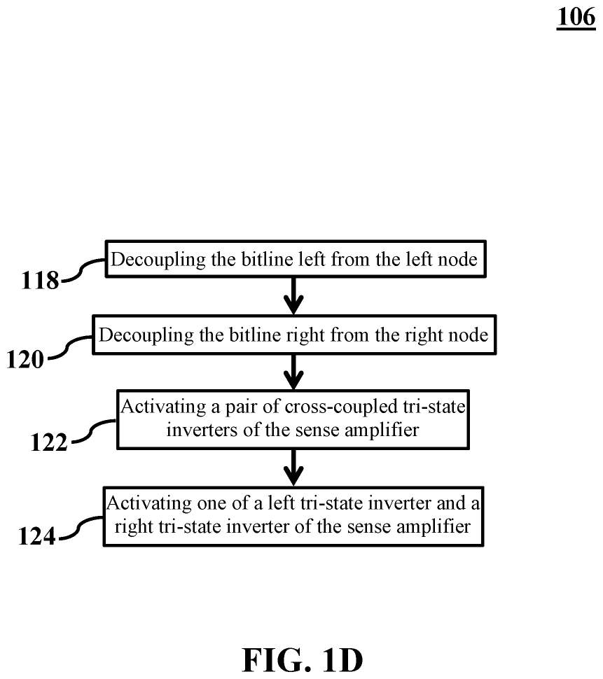

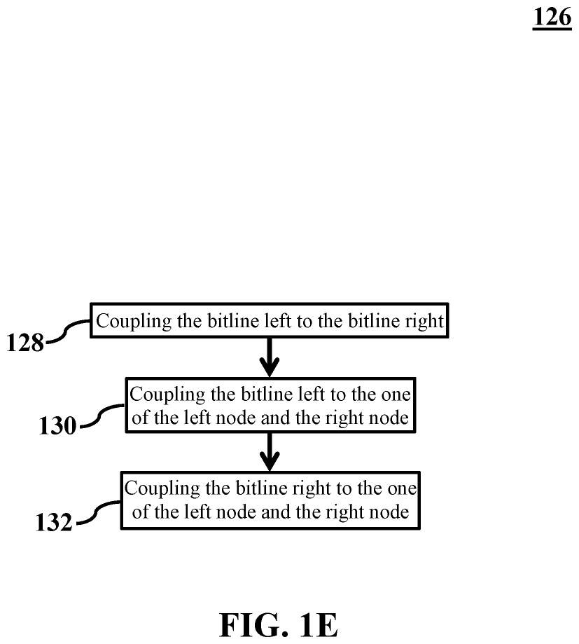

FIG. 1A shows a flowchart of a method for accessing a memory cell in a semiconductive memory device, consistent with one or more exemplary embodiments of the present disclosure. In an exemplary embodiment, a method 100 may include equalizing a bitline left and a bitline right of the semiconductive memory device (step 102), charge sharing between the memory cell and one of the bitline left and the bitline right (step 104), and driving one of a left node and a right node of a sense amplifier to a data voltage level (step 106).

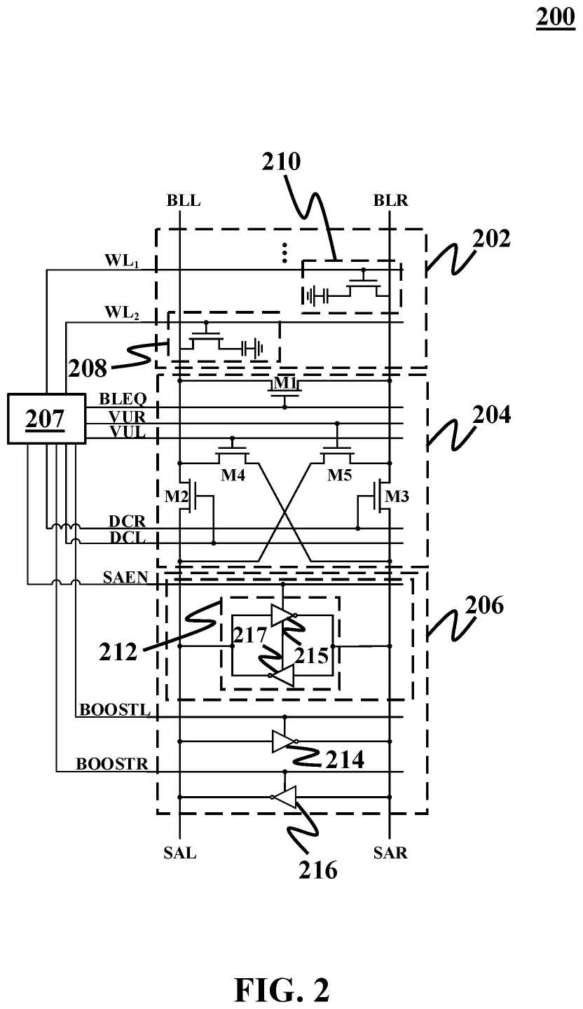

FIG. 2 shows a schematic of a semiconductive memory device, consistent with one or more exemplary embodiments of the present disclosure. Referring to FIGS. 1A and 2, in an exemplary embodiment, different steps of method 100 may be implemented utilizing a semiconductive memory device 200 or a similar semiconductive memory device. In an exemplary embodiment, semiconductive memory device 200 may include a dynamic random-access memory (DRAM). In an exemplary embodiment, semiconductive memory device 200 may include a plurality of memory cells 202, a charge sharing circuit 204 and a sense amplifier 206. In an exemplary embodiment, charge sharing circuit 204 may couple/decouple sense amplifier 206 from a bitline left BLL and a bitline right BLR of semiconductive memory device 200. In an exemplary embodiment, each of plurality of memory cells 202 may be coupled to one of bitline left BLL or a bitline right BLR. An exemplary data stored in each of plurality of memory cells 202 may be accessed through a respective bitline. An exemplary data stored in each of plurality of memory cells 202 may be extracted from a left node SAL and a right node SAR of sense amplifier 206.

For further detail with respect to step 102, FIG. 1B shows a flowchart of a method for equalizing a bitline left and a bitline right of a semiconductive memory device, consistent with one or more exemplary embodiments of the present disclosure. In an exemplary embodiment, equalizing the bitline left and the bitline right may include coupling the bitline left to the bitline right (step 108), coupling the bitline left to the left node (step 110), and coupling the bitline right to the right node (step 112). Referring to FIGS. 1B and 2, in an exemplary embodiment, step 108 may include coupling bitline left BLL to bitline right BLR. In an exemplary embodiment, step 110 may include coupling bitline left BLL to left node SAL. In an exemplary embodiment, step 112 may include coupling bitline right BLR to right node SAR. In an exemplary embodiment, bitline left BLL and bitline right BLR may be equalized utilizing charge sharing circuit 204. In an exemplary embodiment, charge sharing circuit 204 may include an equalizing transistor M1, a first coupling transistor M2, and a second coupling transistor M3. In an exemplary embodiment, steps 108-110 may be implemented utilizing equalizing transistor M1, coupling transistor M2, and coupling transistor M3. In an exemplary embodiment, each of equalizing transistor M1, coupling transistor M2, and coupling transistor M3 may include one of positive-channel metal oxide semiconductor (PMOS) or negative-channel MOS (NMOS) transistors. In an exemplary embodiment, a source of equalizing transistor Ml may be connected to bitline left BLL and a drain of equalizing transistor M1 may be connected to bitline right BLR. In an exemplary embodiment, a source of coupling transistor M2 may be connected to left node SAL and a drain of coupling transistor M2 may be connected to bitline left BLL. In an exemplary embodiment, a source of coupling transistor M3 may be connected to right node SAR and a drain of coupling transistor M3 may be connected to bitline right BLR.

In an exemplary embodiment, accessing a memory cell in semiconductive memory device 200 may require voltages of bitline left BLL and bitline right BLR to be equal because an unintended voltage difference between bitline left BLL and bitline right BLR may cause sense amplifier 206 to drive left node SAL and right node SAR to unexpected voltage levels, resulting in erroneous memory cell data extraction. Exemplary voltages of bitline left BLL and bitline right BLR may be unequal due to a noise in semiconductive memory device 200. Therefore, in an exemplary embodiment, voltages of bitline left BLL and bitline right BLR may need to be equalized before an access to a memory cell.

In further detail regarding step 108 in context of FIG. 2, in an exemplary embodiment, bitline left BLL may be coupled to bitline right BLR responsive to equalizing transistor Ml being activated. To activate equalizing transistor M1, in an exemplary embodiment, a bitline equalizing control signal BLEQ may be applied to a gate of equalizing transistor M1. In each step of method 100, an exemplary voltage level of control signal BLEQ may be controlled utilizing a memory controller 207. In an exemplary embodiment, memory controller 207 may include a hardwired control unit. An exemplary hardwired control unit may generate a number of control signals utilizing a finite state machine. An exemplary hardwired control unit may be implemented utilizing a logic circuit. In an exemplary embodiment, memory controller 207 may implement different steps of method 100 by activating/deactivating transistors of semiconductive memory device 200. In an exemplary embodiment, semiconductive memory device 200 may receive a request from a processor including an address of a specific memory cell in semiconductive memory device 200. In an exemplary embodiment, upon receiving a request, memory controller 207 may sequentially generate a set of control signals in a timely manner. Exemplary control signals may activate a subset of transistors of semiconductive memory device 200, resulting in extracting data stored in a specific memory cell with an address as that of received request. Exemplary time cycles of generated control signals may be set according to hardware characteristics of semiconductive memory device 200 such as parasitic capacitance of bitlines and activation/deactivation time of transistors. Specifically, a voltage level of a bitline with higher parasitic capacitance may take a longer time to reach a steady-state value. Therefore, in an exemplary embodiment, memory controller 207 may generate control signals with larger time cycles for a proper data extraction. When equalizing transistor M1 is an exemplary NMOS transistor, equalizing transistor Ml may be activated by driving control signal BLEQ to a voltage level of an activating power supply of semiconductive memory device 200. An exemplary activating power supply may be provided by a VPP pin of DRAM chips. A pair of bitlines in a conventional DRAM may be precharged to VDD/2 before a charge sharing phase. However, a voltage level of a memory cell may be either 0 or VDD corresponding to logical values of 0 or 1. As a result, an equalization between a pair of bitlines in conventional DRAMs include driving a 0 or VDD voltage to VDD/2, resulting in power and time consumption. In contrast, in an exemplary embodiment, a voltage level of both bitlines in semiconductive memory device 200 may be equal to one of 0 or VDD before a charge sharing phase. As a result, in an exemplary embodiment, a precharing phase may not be needed in semiconductive memory device 200.

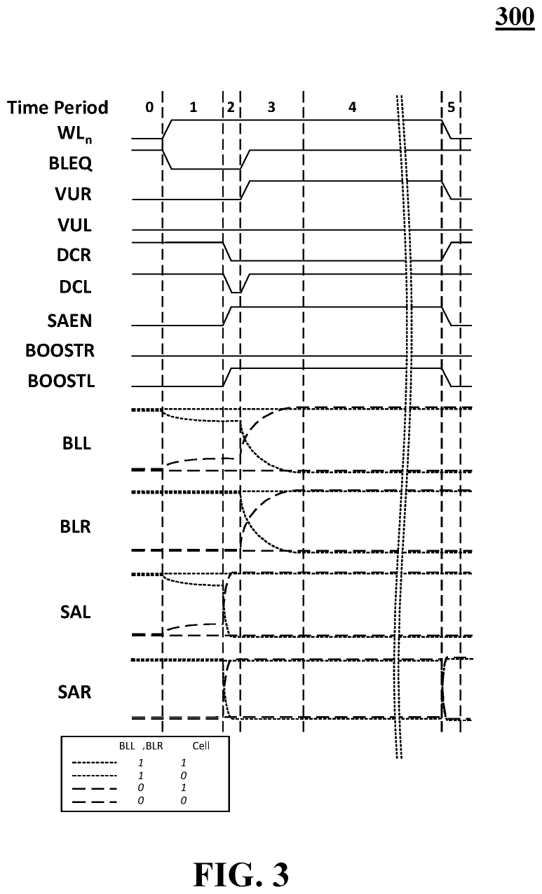

FIG. 3 shows graphs 300 of voltage levels of a bitline left, a bitline right, and control signals in different time periods for accessing a bitline left, consistent with one or more exemplary embodiments of the present disclosure. In an exemplary embodiment, a method similar to step 102 of FIG. 1B may be conducted on an exemplary semiconductive memory device similar to semiconductive memory device 200 of FIG. 2. Besides, in an exemplary embodiment, graphs 300 in FIG. 3 represent voltage levels of bitline left BLL, bitline right BLR, and control signals of semiconductive memory device 200 of FIG. 2. Referring to FIGS. 1B, 2 and 3, in an exemplary embodiment, in a time period 0, control signal BLEQ may be driven to a voltage level of the activating power supply, and voltage levels of bitline left BLL and bitline right BLR may be equal.

For further detail with regard to step 110 in context of FIG. 2, in an exemplary embodiment, bitline left BLL may be coupled to left node SAL responsive to coupling transistor M2 being activated. To activate coupling transistor M2, in an exemplary embodiment, a left coupling control signal DCL may be applied to a gate of coupling transistor M1. In each step of method 100, an exemplary voltage level of control signal DCL may be controlled utilizing memory controller 207. When coupling transistor M2 is an exemplary NMOS transistor, coupling transistor M2 may be activated by driving control signal DCL to a voltage level of the activating power supply. In an exemplary embodiment, a voltage level of both bitline left BLL and left node SAL may be equal to one of 0 or VDD after coupling bitline left BLL to left node SAL.

In further detail with respect to step 112 in context of FIG. 2, in an exemplary embodiment, bitline right BLR may be coupled to right node SAR responsive to coupling transistor M3 being activated. To activate coupling transistor M3, in an exemplary embodiment, a right coupling control signal DCR may be applied to a gate of coupling transistor M2. In each step of method 100, an exemplary voltage level of control signal DCR may be controlled utilizing memory controller 207. When coupling transistor M3 is an exemplary NMOS transistor, coupling transistor M3 may be activated by driving control signal DCR to a voltage level of the activating power supply. In an exemplary embodiment, a voltage level of both bitline right BLR and right node SAR may be equal to one of 0 or VDD after coupling bitline right BLR to right node SAR. In an exemplary embodiment, steps 108-112 may equalize voltage levels of bitline left BLL, bitline right BLR, left node SAL, and SAR. In other words, in an exemplary embodiment, a voltage level of each of bitline left BLL, bitline right BLR, left node SAL, and SAR may be equal to one of 0 or VDD before a charge sharing phase, as in time period 0 of FIG. 3.

Referring to FIG. 1A, 2 and 3, in an exemplary embodiment, step 104 may include charge sharing between the memory cell and one of bitline left BLL and bitline right BLR. Exemplary charges of the memory cell and the one of bitline left BLL and bitline right BLR may be shared utilizing charge sharing circuit 204. An exemplary charge sharing phase is shown in a time period 1 of FIG. 3.

For further detail regarding step 104, FIG. 1C shows a flowchart of a method for charge sharing between a memory cell and one of a bitline left and a bitline right, consistent with one or more exemplary embodiments of the present disclosure. In an exemplary embodiment, charge sharing between the memory cell and the one of the bitline left and the bitline right may include decoupling the bitline left from the bitline right (step 114) and coupling the memory cell to the one of the bitline right and the bitline left (step 116). Referring to FIGS. 1C and 2, in an exemplary embodiment, step 114 may include decoupling bitline left BLL from bitline right BLR. In an exemplary embodiment, step 116 may include coupling the memory cell to the one of bitline right BLR and bitline left BLL. An exemplary memory cell may be coupled to one of bitline left BLL or bitline right BLR. In an exemplary embodiment, a memory cell 208 of plurality of memory cells 202 may be coupled to bitline left BLL. In an exemplary embodiment, a memory cell 210 of plurality of memory cells 202 may be coupled to bitline right BLR. In an exemplary embodiment, step 104 may include charge sharing between memory cell 208 and bitline left BLL or between memory cell 210 and bitline right BLR.

In further detail with regard to step 114 in context of FIG. 2, in an exemplary embodiment, bitline left BLL may be decoupled from bitline right BLR responsive to equalizing transistor M1 being deactivated. To deactivate equalizing transistor M1, in an exemplary embodiment, control signal BLEQ may be applied to the gate of equalizing transistor M1. When equalizing transistor M1 is an exemplary NMOS transistor, equalizing transistor M1 may be deactivated by driving control signal BLEQ to a logic low voltage.

For further detail with respect to step 116 in context of FIG. 2, an exemplary memory cell may be coupled to the one of bitline right BLR and bitline left BLL responsive to a wordline of semiconductive memory device 200 being driven to a predetermined voltage level. An exemplary predetermined voltage level may include the high logic voltage. An exemplary wordline may include either a first wordline WL₁ or a second wordline WL₂. In an exemplary embodiment, wordline WL₁ may be connected to memory cell 210. In an exemplary embodiment, wordline WL₂ may be connected to memory cell 208. In an exemplary embodiment, only one of wordline WL₁ or wordline WL₂ may be activated (that is, driven to the high logic voltage) during the charge sharing phase. An exemplary address of memory cell may determine whether wordline WL₂ or wordline WL₁ is activated. An exemplary address decoder of semiconductive memory device 200 may receive a row address and activate a respective wordline. An exemplary row address may determine whether a memory cell is connected to bitline left BLL or bitline right BLR. An exemplary least significant bit (LSB) of the row address may determine whether memory cell 208 or memory cell 210 is accessed. Specifically, an exemplary LSB of the row address being equal to 1 may indicate that memory cells connected to a respective wordline are also connected to bitline right BLR. Conversely, an exemplary LSB of the row address being equal to 0 may indicate that memory cells connected to a respective wordline are also connected to bitline left BLL. In an exemplary embodiment, wordline WL₂ may be applied to a gate of an access transistor of memory cell 208. In an exemplary embodiment, the access transistor may be activated by activating wordline WL₂, and hence, a capacitor of memory cell 208 may be coupled to bitline left BLL.

In an exemplary embodiment, charge sharing between memory cell 208 and bitline left BLL or between memory cell 210 and bitline right BLR may result in a voltage perturbation on voltages of bitline left BLL or bitline right BLR when a voltage of bitlines differs from a voltage of memory cells. In contrast, in an exemplary embodiment, charge sharing between memory cell 208 and bitline left BLL or between memory cell 210 and bitline right BLR may not change a voltage of bitline left BLL or bitline right BLR when a voltage of bitlines is equal to a voltage of memory cells. In an exemplary embodiment, the one of bitline left BLL and bitline right BLR may be floating during a charge sharing phase because bitline left BLL and bitline right BLR may be decoupled from power supply VDD or ground. In an exemplary embodiment, a voltage of bitline left BLL and bitline right BLR may be equal to 0 before the charge sharing phase, and a voltage of memory cell 208 or memory cell 210 may be equal to 0 as well. As a result, in an exemplary embodiment, charge sharing in step 104 may not change voltages of bitline left BLL and bitline right BLR. Similarly, in an exemplary embodiment, a voltage of bitline left BLL and bitline right BLR may be equal to VDD before the charge sharing phase, and a voltage of memory cell 208 or memory cell 210 may be equal to VDD as well. As a result, in an exemplary embodiment, charge sharing in step 104 may not change voltages of bitline left BLL and bitline right BLR. In contrast, in an exemplary embodiment, a voltage of bitline left BLL and bitline right BLR may be equal to 0 before the charge sharing phase while a voltage of memory cell 208 or memory cell 210 is equal to VDD. As a result, in an exemplary embodiment, charge sharing in step 104 may cause a voltage perturbation on bitline left BLL or bitline right BLR. Similarly, in an exemplary embodiment, a voltage of bitline left BLL and bitline right BLR may be equal to VDD before the charge sharing phase while a voltage of memory cell 208 or memory cell 210 is equal to 0. As a result, in an exemplary embodiment, charge sharing in step 104 may cause a voltage perturbation on bitline left BLL or bitline right BLR. In an exemplary embodiment, a value of the voltage perturbation may be equal to:

$${V}_{s} = {V}_{DD} \frac{{C}_{cell}}{{C}_{cell} + {C}_{BL}} \qquad Equation ( 1 )$$

where C_{cell} is a capacitance of a memory cell and C_{BL} is a parasitic capacitance of each of bitline left BLL and bitline right BLR. In an exemplary embodiment, Table I represents voltage levels of bitline left BLL, bitline right BLR, and one of memory cell 208 and memory cell 210 (that is, memory cell 208 when bitline left BLL is accessed and memory cell 210 when bitline right BLR accessed) before and after charge sharing.

TABLE I
Voltage levels of BLL, BLR, and memory
cell before and after charge sharing

| BLL/BLR | BLL Voltage Level | BLR Voltage Level | Memory |
|---|---|---|---|
| Access | (Before → After) | (Before → After) | Cell |
| BLL | 0 → 0 | 0 → 0 | 0 → 0 |
| BLL | 0 → Vₛ | 0 → 0 | VDD → Vₛ |
| BLL | VDD → VDD − Vₛ | VDD → VDD | 0 → VDD − Vₛ |
| BLL | VDD → VDD | VDD → VDD | VDD → VDD |
| BLR | 0 → 0 | 0 → 0 | 0 → 0 |
| BLR | 0 → 0 | 0 → Vₛ | VDD → Vₛ |
| BLR | VDD → VDD | VDD → VDD − Vₛ | 0 → VDD − Vₛ |
| BLR | VDD → VDD | VDD → VDD | VDD → VDD |

Referring again to FIGS. 1A and 2, in an exemplary embodiment, step 106 may include driving the one of left node SAL and right node SAR to the data voltage level. An exemplary data voltage level may be associated with stored data in the memory cell. In other words, in an exemplary embodiment, a voltage level of one of memory cell 208 or memory cell 210 may be equal to a data voltage level. Specifically, in an exemplary embodiment, stored data in memory cell 208 or memory cell 210 may be equal to logic zero. Therefore, in an exemplary embodiment, a data voltage level may be equal to 0 V. In contrast, in an exemplary embodiment, stored data in memory cell 208 or memory cell 210 may be equal to logic one. Therefore, in an exemplary embodiment, a data voltage level may be equal to VDD. In an exemplary embodiment, left node SAL may be driven to the data voltage level (that is, either zero or VDD) when controller 207 configures semiconductive memory device 200 to access memory cell 208. In an exemplary embodiment, controller 207 may configure semiconductive memory device 200 to access memory cell 208 responsive to an address received from a processor, as described above. In an exemplary embodiment, right node SAR may be driven to the data voltage level (that is, either zero or VDD) when controller 207 configures semiconductive memory device 200 to access memory cell 210. In an exemplary embodiment, controller 207 may configure semiconductive memory device 200 to access memory cell 210 responsive to an address received from a processor, as described above.

In further detail regarding step 106, FIG. 1D shows a flowchart of a method for driving one of a left node and a right node of a sense amplifier to a data voltage level, consistent with one or more exemplary embodiments of the present disclosure. In an exemplary embodiment, driving the one of the left node and the right node may include decoupling the bitline left from the left node (step 118), decoupling the bitline right from the right node (step 120), activating a pair of cross-coupled inverters of the sense amplifier (step 122), and activating one of a left inverter and a right inverter of the sense amplifier (step 124). Referring to FIGS. 1D, 2 and 3, in an exemplary embodiment, step 118 may include decoupling bitline left BLL from left node SAL. In an exemplary embodiment, step 120 may include decoupling bitline right BLR from right node SAR. In an exemplary embodiment, step 122 may include activating a pair of cross-coupled inverters of sense amplifier 206. In an exemplary embodiment, step 124 may include activating one of a left inverter and a right inverter of sense amplifier 206.

In an exemplary embodiment, coupling transistor M2 and coupling transistor M3 may be kept activated during a charge sharing phase, that is time period 1. As a result, a voltage level of bitline left BLL and left node SAL, and a voltage level of bitline right BLR and right node SAR may be equal before activating sense amplifier 206. In an exemplary embodiment, the one of left node SAL and right node SAR may be driven to the data voltage level responsive to a voltage level of each of left node SAL and right node SAR being equal to a primary voltage level. An exemplary primary voltage level may include one of the logic high voltage or the logic low voltage. An exemplary primary voltage level may be approximately equal to one of the logic high voltage and the logic low voltage. An exemplary logic high voltage may be equal to a VDD voltage level. An exemplary logic low voltage may be equal to a ground voltage level. Exemplary voltage levels of control signals for driving the left node SAL to the data voltage level (that is, accessing memory cell 208) are shown in a time period 2 of FIG. 3.

In an exemplary embodiment, sense amplifier 206 may include a pair of cross-coupled inverters 212, a left inverter 214, and a right inverter 216. In an exemplary embodiment, each inverter of cross-coupled inverters 212 may include a respective tri-state inverter. In an exemplary embodiment, each of left inverter 214 and right inverter 216 may include a respective tri-state inverter. In an exemplary embodiment, cross-coupled inverters 212 may be connected to left node SAL and right node SAR. An exemplary input of left inverter 214 may be connected to left node SAL. An exemplary output of left inverter 214 may be connected to right node SAR. An exemplary input of right inverter 216 may be connected to right node SAR. An exemplary output of right inverter 216 may be connected to left node SAL.

For further detail with regard to step 118 in context of FIG. 2, in an exemplary embodiment, bitline left BLL may be decoupled from left node SAL responsive to coupling transistor M2 being deactivated. To deactivate coupling transistor M2, in an exemplary embodiment, control signal DCL may be applied to the gate of coupling transistor M2. When coupling transistor M2 is an exemplary NMOS transistor, coupling transistor M2 may be deactivated by driving control signal DCL to the logic low voltage. In an exemplary embodiment, by decoupling bitline left BLL from left node SAL, a voltage level of bitline left BLL may be constant during stabilization of sense amplifier 206 while a voltage level of left node SAL may vary during stabilization, that is time period 2.

In further detail with respect to step 120 in context of FIG. 2, in an exemplary embodiment, bitline right BLR may be decoupled from right node SAR responsive to coupling transistor M3 being deactivated. To deactivate coupling transistor M3, in an exemplary embodiment, control signal DCR may be applied to the gate of coupling transistor M3. When coupling transistor M3 is an exemplary NMOS transistor, coupling transistor M3 may be deactivated by driving control signal DCR to the logic low voltage. In an exemplary embodiment, by decoupling bitline right BLR from right node SAR, a voltage level of bitline right BLR may be constant during stabilization of sense amplifier 206 while a voltage level of right node SAR may vary during stabilization, that is time period 2.

For further detail regarding step 122 in context of FIG. 2, in an exemplary embodiment, cross-coupled inverters 212 may be activated responsive to an enabling signal SAEN being driven to a first voltage level. In an exemplary embodiment, when enabling signal SAEN is driven to the logic low voltage, cross-coupled inverters 212 may be decoupled from left node SAL and right node SAR. In contrast, in an exemplary embodiment, when enabling signal SAEN is driven to a voltage level of the activating power supply, cross-coupled inverters 212 may be coupled to both left node SAL and right node SAR. Exemplary voltages of left node SAL and right node SAR may be respectively equal to voltages of bitline left BLL and bitline right BLR right after the charge sharing phase, that is, voltage levels in Table I. Exemplary voltages of left node SAL and right node SAR may be converged to different values when cross-coupled inverters 212 are activated. Exemplary voltages of left node SAL and right node SAR may be converged after some amount of time, that is, a time required for sense amplifier 206 to be stabilized. In an exemplary embodiment, one of left node SAL and right node SAR with lower voltage may be discharged to 0 and a node with higher voltage may be charged to VDD by positive feedback of cross-coupled inverters 212. However, in an exemplary embodiment, voltages of left node SAL and right node SAR may not be converged to desired values when voltages of bitline left BLL and bitline right BLR are equal right after the charge sharing phase. In an exemplary embodiment, left inverter 214 and right inverter 216 may be utilized to converge voltage levels of left node SAL and right node SAR to desired values.

In further detail with respect to step 124 in context of FIG. 2, in an exemplary embodiment, the one of left inverter 214 and right inverter 216 may be activated responsive to a respective boost signal being driven to a second voltage level. In other words, in an exemplary embodiment, left inverter 214 may be activated when left node SAL is driven to the data voltage level, that is, voltage level of memory cell 208. Similarly, in an exemplary embodiment, right inverter 216 may be activated when right node SAR is driven to the data voltage level, that is, voltage level of memory cell 210. In an exemplary embodiment, only one of left inverter 214 or a right inverter 216 may be activated at a given time instant. In an exemplary embodiment, left inverter 214 may be activated by driving a left boost control signal BOOSTL to a voltage level of the activating power supply. In an exemplary embodiment, right inverter 216 may be activated by driving a right boost control signal BOOSTR to a voltage level of the activating power supply. In an exemplary embodiment, a voltage level of each of control signal BOOSTL and control signal BOOSTR may be controlled by memory controller 207. In an exemplary embodiment, memory controller 207 may drive control signal BOOSTL to a voltage level of the activating power supply when wordline WL₂ is activated, that is, a memory cell coupled to bitline left BLL is accessed. Conversely, in an exemplary embodiment, memory controller 207 may drive control signal BOOSTR to a voltage level of the activating power supply when wordline WL₁ is activated, that is, a memory cell coupled to bitline right BLR is accessed.

In an exemplary embodiment, by driving control signal BOOSTL, left inverter 214 may drive left node SAL and right node SAR in parallel with an inverter 215 of cross-coupled inverters 212. Therefore, in an exemplary embodiment, left inverter 214 and inverter 215 may drive left node SAL in a race condition with an inverter 217 of cross-coupled inverters 212 that drives right node SAR. As a result, in an exemplary embodiment, when voltage levels of left node SAL and right node SAR are equal (VDD or 0), left node SAL is dominant to determine a stabilization point. In other words, in an exemplary embodiment, a voltage level of left node SAL may be equal to 0 and a voltage level of right node SAR may be equal to VDD when a voltage level of left node SAL is 0 right after charge sharing. In contrast, in an exemplary embodiment, a voltage level of left node SAL may be equal to VDD and a voltage level of right node SAR may be equal to 0 when a voltage level of left node SAL is VDD right after charge sharing. Table II shows voltage levels of left node SAL and right node SAR before and after stabilization of sense amplifier 206.

TABLE II
Voltage levels of SAL and SAR, before and
after stabilization of sense amplifier

| | | |
|---|---|---|
| BLL/BLR | Before Stabilization | After Stabilization |

| Access | SAL | SAR | SAL | SAR |
|---|---|---|---|---|
| BLL | 0 | 0 | 0 | VDD |
| BLL | Vₛ | 0 | VDD | 0 |
| BLL | VDD − Vₛ | VDD | 0 | VDD |
| BLL | VDD | VDD | VDD | 0 |
| BLR | 0 | 0 | VDD | 0 |
| BLR | 0 | Vₛ | 0 | VDD |
| BLR | VDD | VDD − Vₛ | VDD | 0 |
| BLR | VDD | VDD | 0 | VDD |

As in Table II, in an exemplary embodiment, when voltage levels of left node SAL and right node SAR are equal (rows 1, 4, 5, and 8), voltage level of accessed side may be dominant. In contrast, in an exemplary embodiment, when voltage levels of left node SAL and right node SAR are unequal (rows 2, 3, 6, and 7), voltage level of a side with higher voltage level may be dominant. Putting Table I and Table II together, in an exemplary embodiment, a respective side of sense amplifier 206 may be driven a data voltage level of a memory cell after stabilization of sense amplifier 206. In an exemplary embodiment, when bitline left BLL is accessed, voltage level of both bitline left BLL and bitline right BLR is 0, and a data voltage level is VDD (second row of Table I and Table II), a voltage level of left node SAL may be driven to VDD.

In an exemplary embodiment, sense amplifier 206 may include two inherently imbalanced sense amplifiers. Each exemplary imbalanced sense amplifier may drive a respective node of left node SAL and right node SAR to the data voltage level. An exemplary left imbalanced sense amplifier may be activated by control signal BOOSTL to drive left node SAL to the data voltage level. An exemplary right imbalanced sense amplifier may be activated by control signal BOOSTR to drive right node SAR to the data voltage level.

After stabilization of sense amplifier 206, an exemplary stored data in memory cell 208 may be extracted from left node SAL or stored data in memory cell 210 may be extracted from right node SAR. An exemplary stored data may be extracted by activating an input/output (I/O) circuit of semiconductive memory device 200. An exemplary I/O circuit may be activated by a column decoder of semiconductive memory device 200.

Referring again to FIGS. 1A, 2 and 3, in an exemplary embodiment, method 100 may further include driving each of bitline left BLL and bitline right BLR to the data voltage level (step 126). In an exemplary embodiment, each of bitline left BLL and bitline right BLR may be driven to the data voltage level utilizing charge sharing circuit 204. In an exemplary embodiment, charge sharing circuit 204 may further include a third coupling transistor M4 and a fourth coupling transistor M5. In an exemplary embodiment, a source of coupling transistor M4 may be connected to right node SAR. In an exemplary embodiment, a drain of coupling transistor M4 may be connected to bitline left BLL. In an exemplary embodiment, a source of coupling transistor M5 may be connected to left node SAL. In an exemplary embodiment, a drain of coupling transistor M5 may be connected to bitline right BLR. In an exemplary embodiment, third coupling transistor M4 may couple left node SAL to bitline right BLR. In an exemplary embodiment, fourth coupling transistor M5 may couple right node SAR to bitline left BLL. Exemplary voltage levels of control signals for driving each of bitline left BLL and bitline right BLR to the data voltage level are shown in a time period 3 of FIG. 3. Accessing an exemplary memory cell may be a destructive process, that is, accessing a memory cell may change a voltage level of a memory cell (such as rows 2, 3, 6, and 7 in Table I). Therefore, in an exemplary embodiment, a voltage of memory cells may be updated after each access. In an exemplary embodiment, step 126 may update a voltage of a memory cell by driving a voltage of the memory cell to the data voltage level.

For further detail with regard step 126, FIG. 1E shows a flowchart of a method for driving each of a bitline left and a bitline right to a data voltage level, consistent with one or more exemplary embodiments of the present disclosure. In an exemplary embodiment, driving each of the bitline left and the bitline right may include coupling the bitline left to the bitline right (step 128), coupling the bitline left to the one of the left node and the right node (step 130), and coupling the bitline right to the one of the left node and the right node (step 132). Referring to FIGS. 1E and 2, in an exemplary embodiment, step 128 may include coupling bitline left BLL to bitline right BLR. In an exemplary embodiment, step 130 may include coupling bitline left BLL to the one of left node SAL and right node SAR. In an exemplary embodiment, step 132 may include coupling bitline right BLR to the one of left node SAL and right node SAR. In an exemplary embodiment, coupling transistor M2 and coupling transistor M3 may be deactivated during stabilization of sense amplifier 206. As a result, voltage levels of left node SAL and bitline left BLL, and voltage levels of right node SAR and bitline right BLR may be different after stabilization of sense amplifier 206. In an exemplary embodiment, voltage levels of bitline left BLL and bitline right BLR may be made equal before starting a new charge sharing phase. Therefore, in an exemplary embodiment, voltage levels of both bitline left BLL and bitline right BLR may be driven to the data voltage level. In an exemplary embodiment, when a data voltage level in a next access is equal to a data voltage level, that is, reading two consecutive 0 or 1, no power may be dissipated on bitline left BLL and bitline BLR for the new access because no voltage changes on bitlines happens for new access. In an exemplary embodiment, power dissipation may occur only when a 1 is accessed after accessing a 0 because a voltage level of bitlines may be driven from 0 to VDD. In contrast, a precharge phase is needed for every new access a in a conventional DRAM. Voltage levels of bitlines may be driven from either 0 or VDD to VDD/2 in a precharge phase of a conventional DRAM. As a result, in an exemplary embodiment, when a bit-flip probability in accessed memory cells is small, a power dissipation of semiconductive memory device 200 may be smaller than a conventional DRAM.

In further detail with respect to step 128 in context of FIG. 2, in an exemplary embodiment, bitline left BLL may be coupled to bitline right BLR responsive to equalizing transistor M1 being activated. Referring to FIGS. 1B, 1E, and 2, in an exemplary embodiment, activating equalizing transistor M1 may be similar to equalizing transistor M1 in step 108.

For further detail regarding step 130 in context of FIG. 2, in an exemplary embodiment, bitline left BLL may be coupled to the one of left node SAL and right node SAL responsive to a respective coupling transistor of coupling transistor M2 and coupling transistor M4 being activated. In an exemplary embodiment, when left node SAL is driven to the data voltage level, bitline left BLL may be coupled to left node SAL responsive to coupling transistor M2 being activated. In contrast, in an exemplary embodiment, when right node SAR is driven to the data voltage level, bitline left BLL may be coupled to right node SAR responsive to coupling transistor M4 being activated. In an exemplary embodiment, a left voltage updater control signal VUL may be applied to a gate of coupling transistor M4. An exemplary voltage level of control signal VUL may be controlled by memory controller 207. In an exemplary embodiment, when coupling transistor M4 is an NMOS transistor, coupling transistor M4 may be activated by driving a voltage level of control signal VUL to a voltage level of the activating power supply.

In further detail with regard to step 132 in context of FIG. 2, in an exemplary embodiment, bitline right BLR may be coupled to the one of left node SAL and right node SAL responsive to a respective coupling transistor of coupling transistor M3 and coupling transistor M5 being activated. In an exemplary embodiment, when left node SAL is driven to the data voltage level, bitline right BLR may be coupled to left node SAL responsive to coupling transistor M5 being activated. In contrast, in an exemplary embodiment, when right node SAR is driven to the data voltage level, bitline right BLR may be coupled to right node SAR responsive to coupling transistor M3 being activated. In an exemplary embodiment, a right voltage updater control signal VUR may be applied to a gate of coupling transistor M5. An exemplary voltage level of control signal VUR may be controlled by memory controller 207. In an exemplary embodiment, when coupling transistor M5 is an NMOS transistor, coupling transistor M5 may be activated by driving a voltage level of control signal VUR to a voltage level of the activating power supply.

Referring to FIGS. 2 and 3, in an exemplary embodiment, after driving each of bitline left BLL and bitline right BLR to the data voltage level, an activation/deactivation status of transistors in charge sharing circuit 204 may be kept fixed until a new address is received by semiconductive memory device 200, that is, a time period 4 of FIG. 3. Data of all memory cells connected to an exemplary wordline, that is, memory cells in adjacent pairs of bitlines, may be available at respective nodes of sense amplifiers. Besides, an exemplary new address may refer to one of memory cells connected to an activated wordline. Therefore, in an exemplary embodiment, by keeping an activation/deactivation status of transistors in charge sharing circuit 204 fixed, data of a new memory cell may be extracted without a new charge sharing and sense amplifier stabilization, resulting in lower latency and power dissipation. Otherwise, in an exemplary embodiment, an activated wordline may be deactivated in time period 5 of FIG. 3.

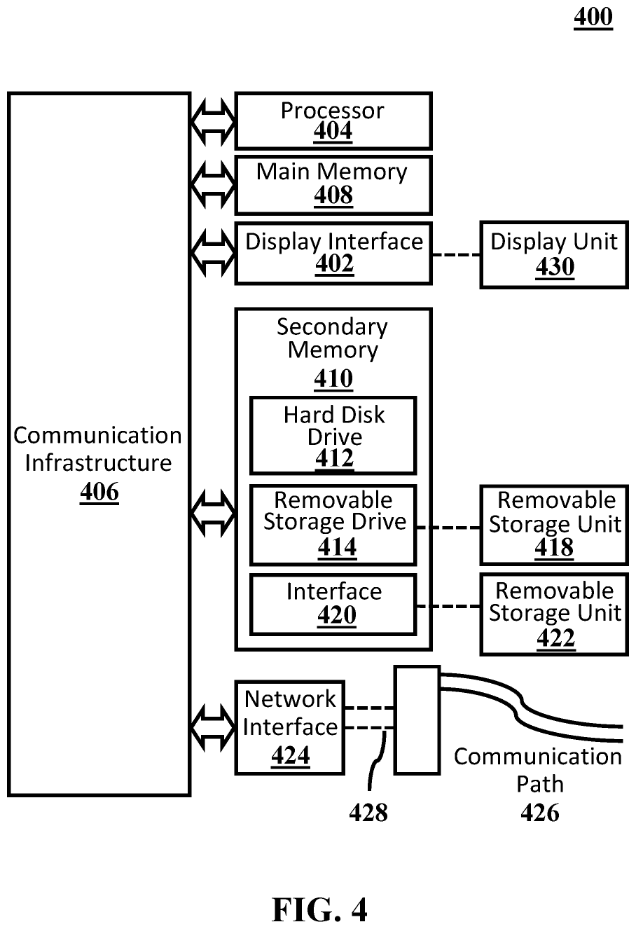

FIG. 4 shows an example computer system 400 in which an embodiment of the present invention, or portions thereof, may be implemented as computer-readable code, consistent with exemplary embodiments of the present disclosure. For example, different steps of method 100 may be implemented in computer system 400 using hardware, software, firmware, tangible computer readable media having instructions stored thereon, or a combination thereof and may be implemented in one or more computer systems or other processing systems. Hardware, software, or any combination of such may embody any of the modules and components in FIGS. 1A-2.

If programmable logic is used, such logic may execute on a commercially available processing platform or a special purpose device. One ordinary skill in the art may appreciate that an embodiment of the disclosed subject matter can be practiced with various computer system configurations, including multi-core multiprocessor systems, minicomputers, mainframe computers, computers linked or clustered with distributed functions, as well as pervasive or miniature computers that may be embedded into virtually any device.

For instance, a computing device having at least one processor device and a memory may be used to implement the above-described embodiments. A processor device may be a single processor, a plurality of processors, or combinations thereof. Processor devices may have one or more processor “cores.”

An embodiment of the invention is described in terms of this example computer system 400. After reading this description, it will become apparent to a person skilled in the relevant art how to implement the invention using other computer systems and/or computer architectures. Although operations may be described as a sequential process, some of the operations may in fact be performed in parallel, concurrently, and/or in a distributed environment, and with program code stored locally or remotely for access by single or multi-processor machines. In addition, in some embodiments the order of operations may be rearranged without departing from the spirit of the disclosed subject matter.

Processor device 404 may be a special purpose (e.g., a graphical processing unit) or a general-purpose processor device. As will be appreciated by persons skilled in the relevant art, processor device 404 may also be a single processor in a multi-core/multiprocessor system, such system operating alone, or in a cluster of computing devices operating in a cluster or server farm. Processor device 404 may be connected to a communication infrastructure 406, for example, a bus, message queue, network, or multi-core message-passing scheme.

In an exemplary embodiment, computer system 400 may include a display interface 402, for example a video connector, to transfer data to a display unit 430, for example, a monitor. Computer system 400 may also include a main memory 408, for example, random access memory (RAM), and may also include a secondary memory 410. Secondary memory 410 may include, for example, a hard disk drive 412, and a removable storage drive 414. Removable storage drive 414 may include a floppy disk drive, a magnetic tape drive, an optical disk drive, a flash memory, or the like. Removable storage drive 414 may read from and/or write to a removable storage unit 418 in a well-known manner. Removable storage unit 418 may include a floppy disk, a magnetic tape, an optical disk, etc., which may be read by and written to by removable storage drive 414. As will be appreciated by persons skilled in the relevant art, removable storage unit 418 may include a computer usable storage medium having stored therein computer software and/or data.

In alternative implementations, secondary memory 410 may include other similar means for allowing computer programs or other instructions to be loaded into computer system 400. Such means may include, for example, a removable storage unit 422 and an interface 420. Examples of such means may include a program cartridge and cartridge interface (such as that found in video game devices), a removable memory chip (such as an EPROM, or PROM) and associated socket, and other removable storage units 422 and interfaces 420 which allow software and data to be transferred from removable storage unit 422 to computer system 400.

Computer system 400 may also include a communications interface 424. Communications interface 424 allows software and data to be transferred between computer system 400 and external devices. Communications interface 424 may include a modem, a network interface (such as an Ethernet card), a communications port, a PCMCIA slot and card, or the like. Software and data transferred via communications interface 424 may be in the form of signals, which may be electronic, electromagnetic, optical, or other signals capable of being received by communications interface 424. These signals may be provided to communications interface 424 via a communications path 426. Communications path 426 carries signals and may be implemented using wire or cable, fiber optics, a phone line, a cellular phone link, an RF link or other communications channels.

In this document, the terms “computer program medium” and “computer usable medium” are used to generally refer to media such as removable storage unit 418, removable storage unit 422, and a hard disk installed in hard disk drive 412. Computer program medium and computer usable medium may also refer to memories, such as main memory 408 and secondary memory 410, which may be memory semiconductors (e.g. DRAMs, etc.).

Computer programs (also called computer control logic) are stored in main memory 408 and/or secondary memory 410. Computer programs may also be received via communications interface 424. Such computer programs, when executed, enable computer system 400 to implement different embodiments of the present disclosure as discussed herein. In particular, the computer programs, when executed, enable processor device 404 to implement the processes of the present disclosure, such as operations in method 100 illustrated by flowcharts of FIGS. 1A-1E discussed above. Accordingly, such computer programs represent controllers of computer system 400. Where an exemplary embodiment of method 100 is implemented using software, the software may be stored in a computer program product and loaded into computer system 400 using removable storage drive 414, interface 420, and hard disk drive 412, or communications interface 424.

Embodiments of the present disclosure also may be directed to computer program products including software stored on any computer useable medium. Such software, when executed in one or more data processing device, causes a data processing device to operate as described herein. An embodiment of the present disclosure may employ any computer useable or readable medium. Examples of computer useable mediums include, but are not limited to, primary storage devices (e.g., any type of random access memory), secondary storage devices (e.g., hard drives, floppy disks, CD ROMS, ZIP disks, tapes, magnetic storage devices, and optical storage devices, MEMS, nanotechnological storage device, etc.).

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

### EXAMPLE

In this example, performance of a semiconductive memory device (similar to semiconductive memory device 200) is demonstrated. A chip power supply (VDD) of the semiconductive memory device is equal to about 1.2 V. A capacitance of a memory cell (similar to each of memory cell 208 and memory cell 210) is equal to about 24 fF. A parasitic capacitance of each of a bitline left (similar to bitline left BLL) and a bitline right (bitline right BLR) is equal to about 144 fF. All transistors of the semiconductive memory device (similar to transistors M1-M5) are of 16 nm predictive technology model.

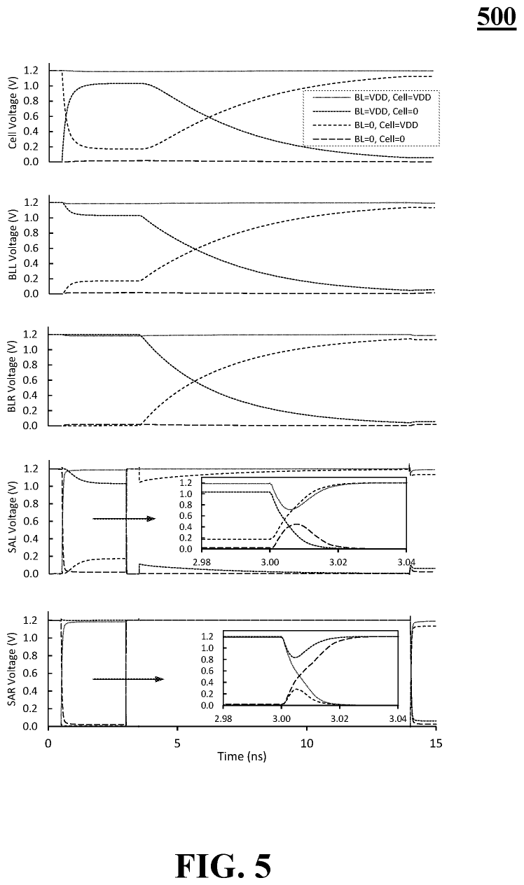

FIG. 5 shows graphs 500 of voltage levels of a memory cell, bitlines, and nodes of a sense amplifier, consistent with one or more exemplary embodiments of the present disclosure. Voltage levels of the memory cell, the bitline left, the bitline right, a left node (similar to left node SAL), and a right node (similar to right node SAL) may change according to voltage levels in Table I and Table II for different initial voltage values of the memory cell, the bitline left, and the bitline right. Besides, voltage levels of lines and nodes are converged in about 14 ns.

While the foregoing has described what may be considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations. This is for purposes of streamlining the disclosure, and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

While various implementations have been described, the description is intended to be exemplary, rather than limiting and it will be apparent to those of ordinary skill in the art that many more implementations and implementations are possible that are within the scope of the implementations. Although many possible combinations of features are shown in the accompanying figures and discussed in this detailed description, many other combinations of the disclosed features are possible. Any feature of any implementation may be used in combination with or substituted for any other feature or element in any other implementation unless specifically restricted. Therefore, it will be understood that any of the features shown and/or discussed in the present disclosure may be implemented together in any suitable combination. Accordingly, the implementations are not to be restricted except in light of the attached claims and their equivalents. Also, various modifications and changes may be made within the scope of the attached claims.

What is claimed is:

1. A semiconductive memory device, comprising:
a sense amplifier configured to drive one of a left node and a right node of the sense amplifier to a data voltage level associated with stored data in a memory cell of the semiconductive memory device responsive to a voltage level of each of the left node and the right node being equal to one of a logic high voltage or a logic low voltage, the sense amplifier comprising:
a pair of cross-coupled inverters configured to be activated responsive to an enabling signal being driven to a first voltage level;
a left inverter, an input of the left inverter coupled to the left node and an output of the left inverter coupled to the right node; and
a right inverter, an input of the right inverter coupled to the right node and an output of the right inverter coupled to the left node,
wherein one of the left inverter and the right inverter is configured to be activated responsive to a respective boost signal being driven to a second voltage level; and
a charge sharing device, comprising:
an equalizing transistor configured to:
couple a bitline left of the semiconductive memory device to a bitline right of the semiconductive memory device responsive to the equalizing transistor being activated; and
decouple the bitline left from the bitline right responsive to the equalizing transistor being deactivated;
a first coupling transistor configured to:
couple the bitline left to the left node responsive to the first coupling transistor being activated; and
decouple the bitline left from the left node responsive to the first coupling transistor being deactivated;
a second coupling transistor configured to:
couple the bitline right to the right node responsive to the second coupling transistor being activated; and
decouple the bitline right from the right node responsive to the second coupling transistor being deactivated;
a third coupling transistor; and
a fourth coupling transistor,
wherein:
one of the first coupling transistor and the third coupling transistor is configured to couple the bitline left to the one of the left node and the right node responsive to a respective coupling transistor of the first coupling transistor and the third coupling transistor being activated; and
one of the second coupling transistor and the fourth coupling transistor configured to couple the bitline right to the one of the left node and the right node responsive to a respective coupling transistor of the second coupling transistor and the fourth coupling transistor being activated.

2. A semiconductive memory device, comprising a sense amplifier configured to drive one of a left node of the sense amplifier and a right node of the sense amplifier to a data voltage level associated with stored data in a memory cell of the semiconductive memory device responsive to a voltage level of each of the left node and the right node being equal to a primary voltage level.

3. The semiconductive memory device of claim 2, wherein the sense amplifier comprises:
a pair of cross-coupled inverters configured to be activated responsive to an enabling signal being driven to a first voltage level;
a left inverter, an input of the left inverter coupled to the left node and an output of the left inverter coupled to the right node; and
a right inverter, an input of the right inverter coupled to the right node and an output of the right inverter coupled to the left node,
wherein one of the left inverter and the right inverter configured to be activated responsive to a respective boost signal being driven to a second voltage level.

4. The semiconductive memory device of claim 2, further comprising:
a charge sharing circuit configured to:
equalize a bitline left and a bitline right of the semiconductive memory device; and
drive each of the bitline left and the bitline right to the data voltage level; and
a wordline configured to couple the memory cell to the one of the bitline right and the bitline left responsive to the wordline being activated.

5. The semiconductive memory device of claim 4, wherein the charge sharing circuit comprises:
an equalizing transistor configured to:
couple the bitline left to the bitline right responsive to the equalizing transistor being activated; and
decouple the bitline left from the bitline right responsive to the equalizing transistor being deactivated;
a first coupling transistor configured to:
couple the bitline left to the left node responsive to the first coupling transistor being activated; and
decouple the bitline left from the left node responsive to the first coupling transistor being deactivated; and
a second coupling transistor configured to:
couple the bitline right to the right node responsive to the second coupling transistor being activated; and
decouple the bitline right from the right node responsive to the second coupling transistor being deactivated.

6. The semiconductive memory device of claim 5, wherein the charge sharing circuit further comprises:
a third coupling transistor; and
a fourth coupling transistor,
wherein:
one of the first coupling transistor and the third coupling transistor configured to couple the bitline left to the one of the left node and the right node responsive to a respective coupling transistor of the first coupling transistor and the third coupling transistor being activated; and
one of the second coupling transistor and the fourth coupling transistor configured to couple the bitline right to the one of the left node and the right node responsive to a respective coupling transistor of the second coupling transistor and the fourth coupling transistor being activated.

7. The semiconductive memory device of claim 2, wherein the primary voltage level comprises one of a logic high voltage or a logic low voltage.

8. A method for accessing a memory cell in a semiconductive memory device, the method comprising driving one of a left node and a right node of a sense amplifier to a data voltage level associated with stored data in the memory cell responsive to a voltage level of each of the left node and the right node being equal to one of a logic high voltage or a logic low voltage.

9. The method of claim 8, further comprising equalizing, utilizing a charge sharing circuit of the semiconductive memory device, a bitline left and a bitline right of the semiconductive memory device prior to driving the one of the left node and the right node.

10. The method of claim 9, further comprising charge sharing between the memory cell and one of the bitline left and the bitline right.

11. The method of claim 10, wherein driving the one of the left node and the right node comprises:
decoupling the bitline left from the left node responsive to a first coupling transistor of the charge sharing circuit being deactivated;
decoupling the bitline right from the right node responsive to a second coupling transistor of the charge sharing circuit being deactivated;
activating a pair of cross-coupled inverters of the sense amplifier responsive to an enabling signal being driven to a first voltage level; and
activating one of a left inverter and a right inverter of the sense amplifier responsive to a respective boost signal being driven to a second voltage level, wherein:
an input of the left inverter is coupled to the left node;
an output of the left inverter is coupled to the right node;
an input of the right inverter is coupled to the right node; and
an output of the right inverter is coupled to the left node.

12. The method of claim 10, wherein equalizing the bitline left and the bitline right comprises:
coupling the bitline left to the bitline right responsive to an equalizing transistor of the charge sharing circuit being activated;
coupling the bitline left to the left node responsive to the first coupling transistor being activated; and
coupling the bitline right to the right node responsive to the second coupling transistor being activated.

13. The method of claim 12, wherein charge sharing between the memory cell and the one of the bitline left and the bitline right comprises:
decoupling the bitline left from the bitline right responsive to the equalizing transistor being deactivated; and
coupling the memory cell to the one of the bitline right and the bitline left responsive to a wordline of the semiconductive memory device being activated.

14. The method of claim 12, further comprising driving, utilizing the charge sharing circuit, each of the bitline left and the bitline right to the data voltage level.

15. The method of claim 14, wherein driving each of the bitline left and the bitline right comprises:
coupling the bitline left to the bitline right responsive to the equalizing transistor being activated;
coupling the bitline left to the one of the left node and the right node responsive to a respective coupling transistor of the first coupling transistor and a third coupling transistor of the charge sharing circuit being activated; and
coupling the bitline right to the one of the left node and the right node responsive to a respective coupling transistor of the second coupling transistor and a fourth coupling transistor of the charge sharing circuit being activated.
